(19) United States
(12) Patent Application Publication
(10) Pub. No.: US 2011/0216044 A1
(43) Pub. Date: Sep. 8, 2011

(54) HOLDING DEVICE FOR STYLUS AND ELECTRONIC DEVICE UTILIZING THE SAME

(75) Inventor: Hui YUAN, Shenzhen City (CN)

(73) Assignees: HONG FU JIN PRECISION INDUSTRY (SHENZHEN) CO., LTD., Shenzhen City (CN); HON HAI PRECISION INDUSTRY CO., LTD., Tu-Cheng (TW)

(21) Appl. No.: 12/916,596

(22) Filed: Oct. 31, 2010

(30) Foreign Application Priority Data
Mar. 3, 2010 (CN) 201010116772.3

(51) Int. Cl. H05K 7/14; G06F 3/033

(52) U.S. Cl. 345/179; 248/534

(57) ABSTRACT

A stylus comprises an annular groove. A holding device for the stylus comprises a hollow tube having a number of first spring tabs. Each first spring tab comprises a prong. The prongs are configured for engaging with the annular groove to hold the stylus in position. An ejecting member is fixed within the hollow tube and configured to apply a spring force to the stylus. When the stylus is pushed inward, the ejecting member is pushed by the stylus and is able to deform to store enough energy to overcome engagement between the prongs and the annular groove when released.

### BACKGROUND

1. Technical Field

The present disclosure relates to a holding device for a stylus of an electronic device.

2. Description of Related Art

Conventional handheld computing devices such as PDAs and e-book readers, often include a touch sensitive display screen and a stylus. The housing of these devices typically includes an elongated slot, which is usually formed adjacent to a sidewall of the housing, and extends downward from the top wall of the housing. The slot is configured to receive and house the stylus.

When the stylus is fully inserted into the slot, the top end of the stylus aligns with the top wall of the housing of the device. As a result, the stylus typically includes a flared tab portion adjacent its top end, so that an operator has something to grasp to enable the removal of the stylus from the slot. The tab portion may even include a rib portion to provide increased friction to further facilitate the removal of the stylus. Despite these attempts to make the removal of the stylus easier, the removal of the stylus can nonetheless be an awkward and difficult process.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric, exploded view of a holding device for a stylus in accordance with an exemplary embodiment.

FIG. 2 is an isometric view showing the stylus held in the holding device of FIG. 1.

FIG. 3 is a cross-sectional view showing the stylus held in the holding device of FIG. 1.

FIG. 4 is a cross-sectional view showing the stylus in a free state.

### DETAILED DESCRIPTION

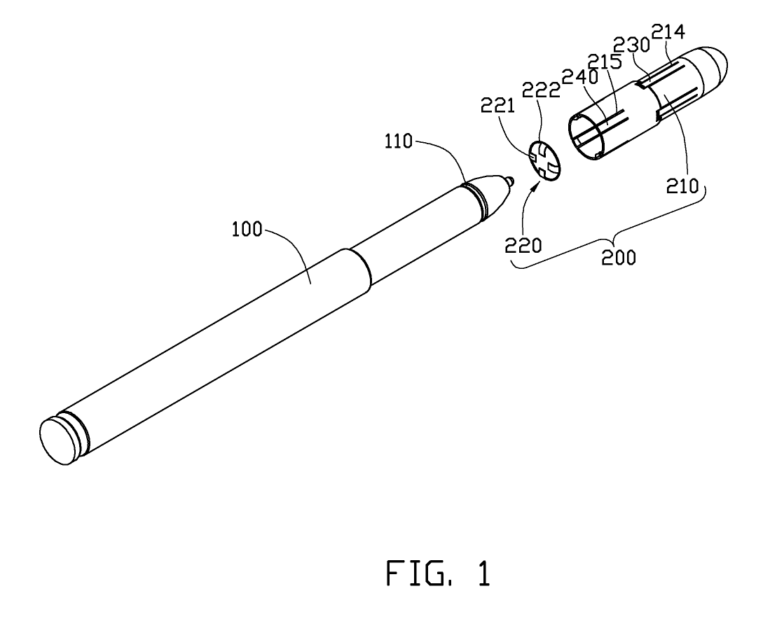

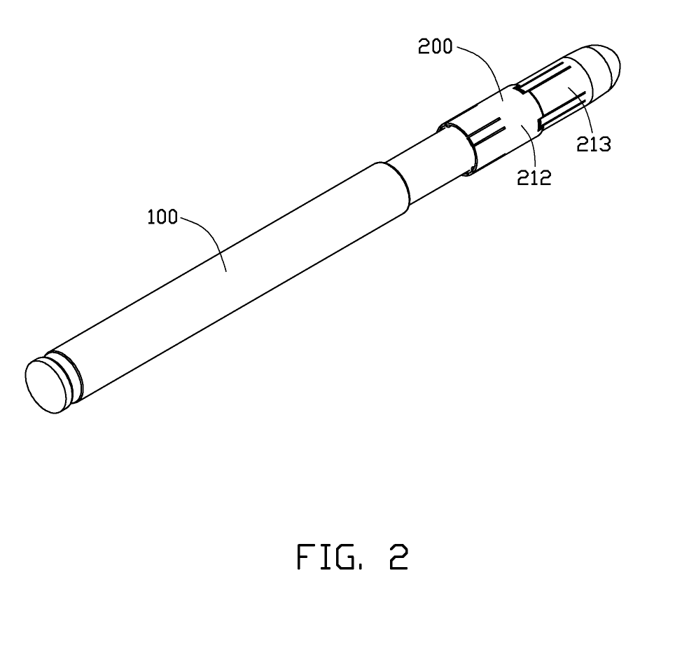

Referring to FIGS. 1-3, an embodiment of a holding device 200 for a stylus 100 is illustrated. The stylus 100 is substantially cylindrical, and defines an annular groove 110 in its circumferential surface adjacent to its end. The holding device 200 can be fixed to an electronic device (not shown), such as a cell phone. The holding device 200 includes a hollow tube 210 and an ejecting member 220. The tube 210 includes a closed end and an open end.

The hollow tube 210 includes a lower portion 212 and a upper portion 213 that has a smaller diameter than that of the lower portion 212. The upper portion 213 defines a number of slots 214 in its lateral surface along a lengthwise direction. A first cantilevered spring tab 230 is formed in each slot 214. Each first spring tab 230 includes a prong 231 at its free end. The lower portion 212 defines a number of slits 215 in its lateral surface. The slits 215 extend from the open end of the tube 210, forming a number of second cantilevered spring tabs 240. Each second spring tab 240 includes a prong 241 at its free end.

The ejecting member 220 includes a circular ring 222 and a number of protruding tabs 221 protruding radially inwardly from the ring 222. The ejecting member 220 is fixed within the tube 210 in a position adjacent to the closed end of the tube 210.

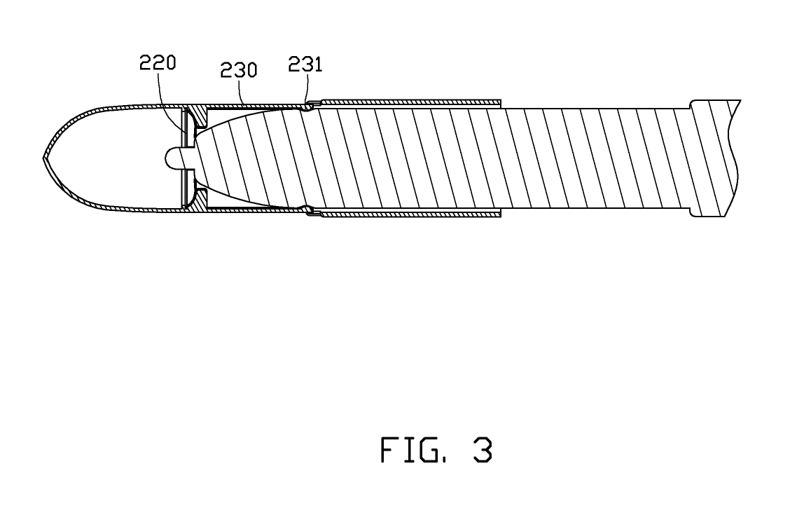

Referring to FIG. 3, the stylus 100 can be held in position by the engagement of the prongs 231 of the first spring tabs 230 with the annular groove 110 of the stylus 100. At this point, the protruding tabs 221 of the ejecting member 220 resist against and apply a spring force to the end of the stylus 100.

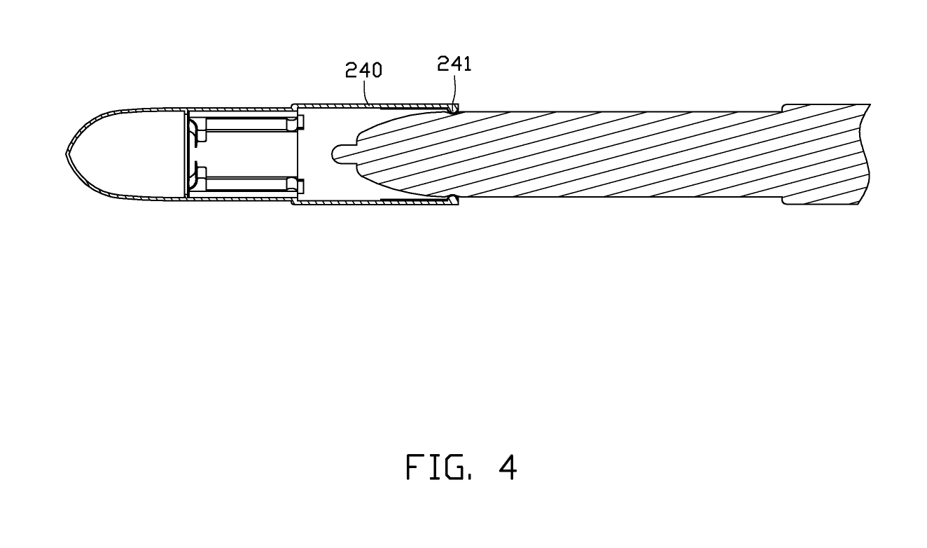

Referring to FIG. 4, when attempting to detach the stylus 100 from the holding device 200, the stylus 100 can be pushed inward to further resist against the protruding tabs 221 of the ejecting member 220. After the pushing to the stylus 100 ceases, the ejecting member 220 pushes the stylus 100 to move. Because the protruding tabs 221 have stored sufficient energy, the engagement between the prongs 231 of the first spring tabs 230 and the annular groove 110 of the stylus 100 can be overcome. The stylus 100 can thus move freely in the tube 210, but cannot move out of the tube 210 without assist from a user because of the engagement between the prongs 241 of the second spring tabs 240 and the annular groove 110 of the stylus 100.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A holding device for a stylus comprising an annular groove, the holding device comprising:
a hollow tube comprising a plurality of first spring tabs, each of the plurality of first spring tabs comprising a prong, the prongs of the plurality of first spring tabs configured for engaging the annular groove to hold the stylus in position; and
an ejecting member fixed within the hollow tube and configured to apply a spring force to the stylus;
wherein when the stylus held in position is pushed inward, the ejecting member is pushed by the stylus and is able to deform to store energy to overcome engagement between the prongs of the plurality of first spring tabs and the annular groove.

2. The holding device according to claim 1, wherein the hollow tube further comprises a plurality of second spring tabs, each of the plurality of second spring tabs comprises a prong, the prongs of the plurality of second spring tabs are configured for engaging the annular groove to prevent the stylus from disengaging from the hollow tube.

3. The holding device according to claim 1, wherein the ejecting member comprises a ring and a number of protruding tabs protruding axially inwardly from the ring, the protruding tabs are able to be deformed.

4. An electronic device comprising:
a stylus comprising an end defining an annular groove in a circumferential surface; and
a holding device for holding the stylus, comprising:
a hollow tube comprising a plurality of first spring tabs, each of the plurality of first spring tabs comprising a prong, the prongs of the plurality of first spring tabs being configured for engaging the annular groove to hold the stylus in position; and
an ejecting member fixed within the hollow tube and configured to apply a spring force to the stylus;
wherein when the stylus held in position is pushed inward, the ejecting member is pushed by the stylus and is able to deform to store energy to overcome engagement between the prongs of the plurality of first spring tabs and the annular groove.

5. The holding device according to claim 4, wherein the hollow tube further comprises a plurality of second spring tabs, each of the plurality of second spring tabs comprises a prong, the prongs of the plurality of second spring tabs are configured for engaging the annular groove to prevent the stylus from disengaging from the hollow tube.

6. The holding device according to claim 4, wherein the ejecting member comprises a ring and a number of protruding tabs protruding axially inwardly from the ring, the protruding tabs are able to be deformed.
